(19) United States
(12) Patent Application Publication
(10) Pub. No.: US 2025/0322894 A1
(43) Pub. Date: Oct. 16, 2025

(54) METHOD OF MANUFACTURING SEMICONDUCTOR DEVICE AND SEMICONDUCTOR DEVICE

(71) Applicant: Renesas Electronics Corporation, Tokyo (JP)

(72) Inventors: Tomoya SAITO, Tokyo (JP); Ken MATSUBARA, Tokyo (JP)

(21) Appl. No.: 19/068,087

(22) Filed: Mar. 3, 2025

Related U.S. Application Data
(60) Provisional application No. 63/634,839, filed on Apr. 16, 2024.

(30) Foreign Application Priority Data
Oct. 21, 2024 (JP) 2024-184974

(51) Int. Cl. G11C 17/18; G11C 11/16; G11C 17/02; G11C 29/02; G11C 29/44; H10B 61/00

(52) U.S. Cl. CPC G11C 17/18; G11C 11/1675; G11C 17/02; G11C 29/028; G11C 29/44; H10B 61/22

(57) ABSTRACT

A write driver writes one of binary data into an OTP memory cell using a boost voltage or a regulator voltage. An OTP voltage select register causes the write driver to select one of two voltages. The trimming registers hold voltage setting values defining magnitudes of two voltages, respectively. An OTP voltage trimming step is a step of sequentially changing the voltage setting values in a high voltage direction while writing is performed into a plurality of OTP memory cells one by one using one of the two voltage setting values as a trimming target, until writing with the same voltage setting value succeeds in succession writing with the same voltage setting value is successively successful in N OTP memory cells.

### CROSS-REFERENCE TO RELATED APPLICATIONS

The disclosures of U.S. Patent Provisional Application No. 63/634,839 filed on Apr. 16, 2024 and Japanese Patent Application No. 2024-184974 filed on Oct. 21, 2024 including the specification, drawings and abstract are incorporated herein by reference in their entirety.

### BACKGROUND

The present invention relates to a method of manufacturing a semiconductor device and a semiconductor device and for example, relates to a technology of a one time programmable (OTP) memory.

There are disclosed techniques listed below.
[Non-Patent Document 1] “Highly Reliable Anti-Fuse Technology in sub-16nm Technologies for Security Applications”, 2016 IEEE International Conference on Integrated Circuit Design and Technology (ICICDT)
[Non-Patent Document 2] “Design Challenges and Solutions of Emerging Nonvolatile Memory for Embedded Applications”, 2021 IEEE International Electron Devices Meeting (IEDM)
[Non-Patent Document 3] “33.1 A 16 nm 32 Mb Embedded STT-MRAM with a 6 ns Read-Access Time, a 1M-Cycle Write Endurance, 20-Year Retention at 150° C. and MTJ-OTP Solutions for Magnetic Immunity”, 2023 IEEE International Solid-State Circuits Conference (ISSCC)

Non-Patent Document 1 discloses a logic NVM cell using an antifuse-programing-mechanism to achieve high density and excellent data storage lifetime. Non-Patent Document 2 discloses that trimming data and the like are written into a magnetoresistive tunnel junction (MTJ)-OTP memory cell before a wafer level chip scale package (WLCSP). Non-Patent Document 3 discloses that a reference current for logic determination of a cell current of an MTJ-OTP memory cell is set between a cell current (I_{P}) in a parallel state and a cell current (I_{BD}) in a dielectric breakdown state.

### SUMMARY

In recent years, in a semiconductor device such as a micro controller unit (MCU) or a system on chip (SoC), there is a growing demand for writing, for example, security information, boot information, and the like to an OTP in addition to trimming data, repair data, and the like. In this case, for example, it is required to increase the capacity of the OTP such as several tens kB to several hundreds kB. As a method for realizing a large-capacity OTP with a small area, it is beneficial to use MTJ-OTP memory cells as disclosed in Non-Patent Document 2 and Non-Patent Document 3 instead of the antifuse-type OTP as disclosed in Non-Patent Document 1.

The MTJ-OTP memory cell is realized by using some memory cells in a spin torque transfer magnetic RAM (STT-MRAM) to cause dielectric breakdown of MTJ elements in the memory cells. At the time of dielectric breakdown of the MTJ element, a voltage higher than a voltage used in normal writing is applied. As a result, a problem of reliability such as a withstand voltage may occur. When the MTJ-OTP memory cell is used to write trimming data and the like, writing to the OTP memory cell is performed in a test step of the STT-MRAM. Therefore, even when a defect occurs due to writing to the OTP memory cell, the defect can be detected in the test step, and outflow of the defective product to the user can be prevented.

Meanwhile, when the MTJ-OTP memory cell is used to write the security information, the boot information, and the like, the writing to the OTP memory cell is performed by the user. Therefore, it is necessary to ensure a reliable write operation to the OTP memory cell by the user. In addition, it is necessary to ensure that no defect occurs due to the write operation to the OTP memory cell by the user.

Embodiments described below are conceived in view of such circumstances, and other problems and novel features are apparent from the description of the present specification and the accompanying drawings.

A method of manufacturing a semiconductor device according to an embodiment includes a wafer process step of forming a nonvolatile memory on a semiconductor wafer and a wafer test step of testing the semiconductor wafer. The wafer test step includes an OTP voltage trimming step. In addition to a plurality of word lines, a plurality of bit lines, a plurality of source lines, and a plurality of OTP memory cells, a charge pump circuit, a voltage regulator circuit, a write driver, an OTP voltage select register, a first trimming register, and a second trimming register are formed in the nonvolatile memory. The plurality of OTP memory cells include MTJ elements that store binary data depending on the presence or absence of dielectric breakdown. The charge pump circuit generates a boost voltage by boosting the power supply voltage. The voltage regulator circuit generates a regulator voltage by stepping down the power supply voltage. The write driver writes one of the binary data to the OTP memory cell by applying a boost voltage or a regulator voltage between the bit line and the source line. The OTP voltage select register causes the write driver to select either the boost voltage or the regulator voltage. The first trimming register and the second trimming register hold a first voltage setting value that defines the magnitude of the boost voltage and a second voltage setting value that defines the magnitude of the regulator voltage, respectively. The OTP voltage trimming step is a step of using one of the first voltage setting value and the second voltage setting value as a voltage setting value to be trimmed and sequentially changing voltage setting values in the high voltage direction until writing with the same voltage setting value succeeds in succession into N OTP memory cells while writing is performed to a plurality of OTP memory cells, one by one.

According to the embodiment, it is possible to guarantee a reliable write operation to the MTJ-OTP memory cell by the user.

### BRIEF DESCRIPTION OF THE DRAWINGS

FIG. 1 is a schematic diagram illustrating a configuration example of a semiconductor device according to an embodiment.

FIG. 2 is a circuit block diagram illustrating a schematic configuration example of a nonvolatile memory in FIG. 1.

FIG. 3 is a schematic diagram illustrating a configuration example and an operation example of a memory cell in FIG. 2.

FIG. 4 is a flowchart illustrating an example of a method of manufacturing the semiconductor device according to an embodiment.

FIG. 5 is a circuit block diagram illustrating a configuration example of a main part focusing on a write operation to an OTP memory area in FIG. 2.

FIG. 6 is a flowchart illustrating an example of detailed processing contents of an OTP voltage trimming step in FIG. 4.

FIG. 7 is a schematic diagram illustrating a specific operation example based on the flow illustrated in FIG. 6.

FIG. 8 is a circuit diagram illustrating a detailed configuration example of the voltage regulator circuit in FIG. 5.

FIG. 9 is a circuit diagram illustrating a schematic configuration example of a charge pump circuit in FIG. 5.

FIG. 10A is a schematic diagram illustrating a layout configuration example of an OTP memory area in FIG. 5.

FIG. 10B is a schematic diagram illustrating a layout configuration example of an OTP memory area in FIG. 5.

FIG. 11 is a flowchart illustrating an example of detailed processing contents of a screening step in FIG. 4.

FIG. 12 is a supplementary view illustrating a part of processing contents in FIG. 11.

FIG. 13 is a circuit block diagram illustrating a configuration example obtained by modifying FIG. 5.

### DETAILED DESCRIPTION

In the following embodiments, when necessary for the sake of convenience, the description is divided into a plurality of sections or embodiments, but unless otherwise specified, the sections or embodiments are not unrelated to each other, and one is related to some or all modifications, details, supplementary explanation, and the like of the other. In addition, in the following embodiments, when the number of elements or the like (including the number, a numerical value, an amount, a range, and the like) is referred to, the number of elements is not limited to a specific number unless otherwise specified or obviously limited to the specific number in principle, and the number of elements may be greater than or equal to or less than or equal to the specific number.

Furthermore, in the following embodiments, it is obvious that components (including elements, steps, and the like) are not necessarily essential unless otherwise specified or considered to be obviously essential in principle. Similarly, in the following embodiments, when the shape, the positional relationship, and the like of the components and the like are referred to, it is assumed to include those substantially approximate or similar to the shape and the like unless otherwise specified or unless clearly considered otherwise in principle. The same applies to the above numerical values and ranges.

In the following embodiment, a p-channel metal oxide semiconductor field effect transistor (MOSFET) and an n-channel MOSFET are referred to as a pMOS transistor and an nMOS transistor, respectively. Hereinafter, embodiments of the present invention are described in detail with reference to the drawings. Note that, in all the drawings illustrating the embodiments, the same members are denoted by the same reference numerals in principle, and repeated description thereof is omitted.

### Outline of Semiconductor Device

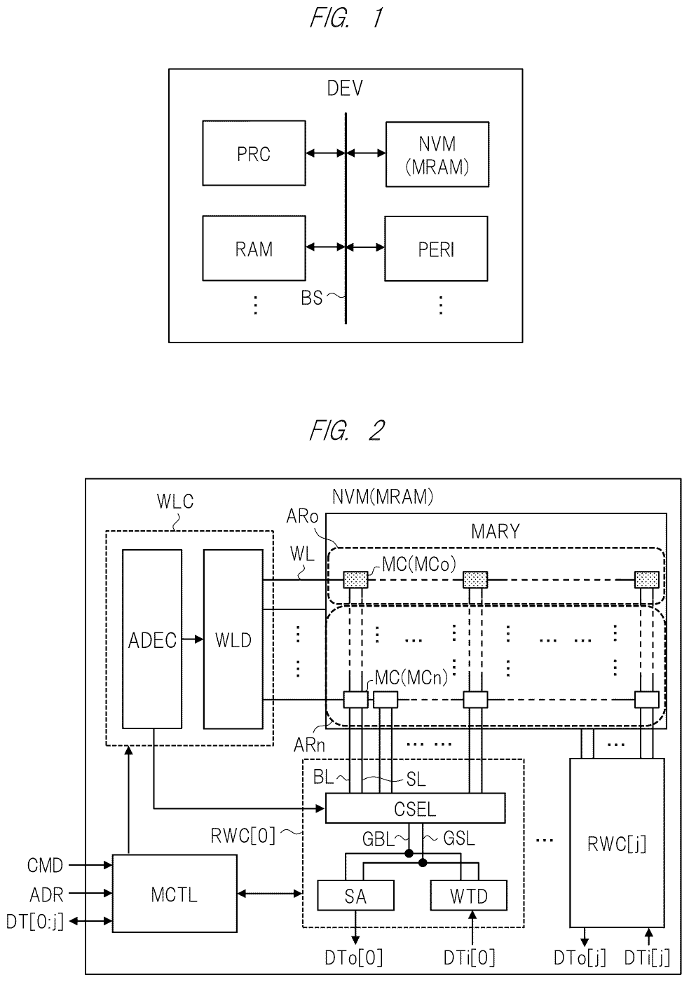

FIG. 1 is a schematic diagram illustrating a configuration example of a semiconductor device according to an embodiment. A semiconductor device DEV illustrated in FIG. 1 is, for example, an MCU or an SoC including one semiconductor chip. The semiconductor device DEV includes internal units connected to each other via a bus BS. Examples of the internal units include a processor PRC, a volatile memory RAM, a nonvolatile memory NVM, and a peripheral circuit PERI.

The volatile memory RAM is, for example, a static random access memory (SRAM). The nonvolatile memory NVM is an STT-MRAM. The processor PRC includes a central processing unit (CPU) and may also include a digital signal processor (DSP), a graphics processing unit (GPU), and the like. The processor PRC executes a predetermined program stored in the STT-MRAM while using, for example, an SRAM or the like as a work memory.

The peripheral circuit PERI is a circuit provided according to the application of the semiconductor device DEV. Examples of the peripheral circuit PERI include a communication interface, an analog/digital converter, a digital/analog converter, various timer circuits, and various analog circuits. Although not illustrated, the semiconductor device DEV also includes a power supply circuit that generates an internal power supply from an external power supply, a clock generation circuit that generates an internal clock signal, and the like.

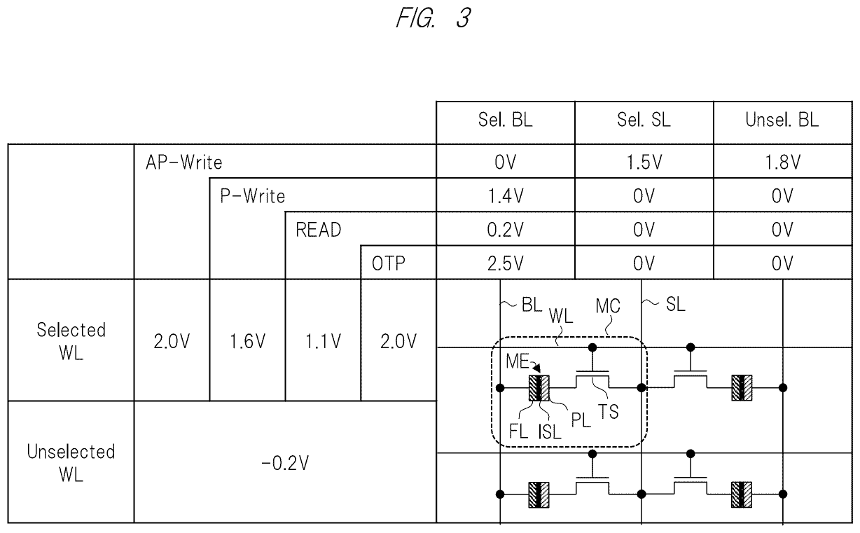

FIG. 2 is a circuit block diagram illustrating a schematic configuration example of the nonvolatile memory NVM in FIG. 1. FIG. 3 is a schematic diagram illustrating a configuration example and an operation example of a memory cell in FIG. 2. The nonvolatile memory NVM, specifically, the STT-MRAM, illustrated in FIG. 2 includes a memory array MARY, a word line control circuit WLC, J (=j+1) read/write control circuits RWC[0]-RWC[j], and a memory control circuit MCTL. The memory array MARY includes a plurality of word lines WL, a plurality of bit lines BL, a plurality of source lines SL, and a plurality of memory cells MC.

The plurality of bit lines BL are arranged to cross the plurality of word lines WL. The plurality of source lines SL are arranged side by side in the plurality of bit lines BL. The plurality of memory cells MC are arranged at intersections of the plurality of word lines WL and the plurality of bit lines BL. Here, the memory array MARY includes a normal memory area ARn and an OTP memory area ARo. The normal memory area ARn includes a normal memory cell MCn which is a part of the plurality of memory cells MC. The OTP memory area ARo includes an OTP memory cell MCo which is another part of the plurality of memory cells MC.

However, the normal memory cell MCn and the OTP memory cell MCo are basically memory cells MC having the same configuration. As illustrated in FIG. 3, the memory cell MC includes a transistor switch TS and an MTJ element ME connected in series between any of the plurality of bit lines BL and any of the plurality of source lines SL. Note that, in this example, a configuration in which two bit lines BL share one source line SL is described.

The transistor switch TS is configured with, for example, an nMOS transistor. One end of the transistor switch TS is connected to the source line SL, and the on/off state of the transistor switch TS is controlled by any of the plurality of word lines WL. One end of the MTJ element ME is connected to the bit line BL, and the other end is connected to the transistor switch TS. The MTJ element ME is configured with a free layer FL and a fixed layer PL that are configured with a magnetic material, and an insulating layer ISL that is provided between the free layer FL and the fixed layer PL and that serves as a tunnel barrier film.

Here, in the normal memory cell MCn, anti parallel (AP) writing or parallel (P) writing is performed as the write operation. In the AP writing, for example, in a state where 2.0 V is applied to the word line WL, the bit line BL is set to 0 V, and 1.5 V is applied to the source line SL. As a result, a write current flows from the source line SL toward the bit line BL, and the magnetization direction of the fixed layer PL and the magnetization direction of the free layer FL become an antiparallel state (AP state). As a result, the MTJ element ME enters a high resistance state (“1” level state).

In the P writing, for example, in a state where 1.6 V is applied to the word line WL, the source line SL is set to 0 V, and 1.4 V is applied to the bit line BL. As a result, a write current flows from the bit line BL toward the source line SL, and the magnetization direction of the fixed layer PL and the magnetization direction of the free layer FL enters a parallel state (P state). As a result, the MTJ element ME enters a low resistance state (“0” level state). In the read operation, for example, in a state where 1.1 V is applied to the word line WL, the source line SL is set to 0 V, and 0.2 V is applied to the bit line BL. Read currents of different magnitudes flow through the memory cell MC according to the AP state or the P state. The determination of the binary data is performed based on the difference in the read current.

Meanwhile, in the OTP memory cell MCo, that is, in the MTJ-OTP memory cell, OTP writing is performed as the write operation. In the OTP writing, for example, in a state where 2.0 V is applied to the word line WL, the source line SL is set to 0 V, and 2.5 V is applied to the bit line BL. Accordingly, dielectric breakdown occurs in the insulating layer ISL. As a result, the MTJ element ME enters an irreversible dielectric breakdown state (BD state) and a further low resistance state (“0” level state).

The MTJ element ME in the OTP memory cell MCo stores binary data depending on the presence or absence of the dielectric breakdown, that is, the AP state/P state or the BD state. Note that, in the OTP writing, a larger write current is required as compared with the AP writing or the P writing. Therefore, more specifically, the OTP memory cell MCo can be configured with the plurality of transistor switches TS connected in parallel, unlike the normal memory cell MCn.

Referring back to FIG. 2, the memory control circuit MCTL inputs a command signal CMD, an address signal ADR, and the like and controls the entire nonvolatile memory NVM according to the input contents. Specifically, the memory control circuit MCTL performs control so that J bits of data signal DT[0:j] (DTi[0:j]) from the outside can be written to the memory cell MC designated by the address signal ADR according to the write command signal CMD. Also, the memory control circuit MCTL performs control so that J bits of the data signal DT[0:j] (DTo[0:j]) from the memory cell MC designated by the address signal ADR can be read to the outside according to the read command signal CMD.

The word line control circuit WLC controls activation/deactivation of the plurality of word lines WL. Specifically, the word line control circuit WLC includes an address decoder ADEC and a word line driver WLD. The address decoder ADEC selects any of the plurality of word lines WL based on the address signal ADR. The word line driver WLD applies a predetermined voltage as described with reference to FIG. 3 to the selected word line WL according to the content of the command signal CMD to activate the word line WL. Note that as illustrated in FIG. 3, the word line driver WLD may apply a negative voltage to the unselected word lines WL.

The J read/write control circuits RWC[0]-RWC[j] are provided corresponding to J bits of data signals DT[0]-DT[j], respectively. Each of the read/write control circuits RWC[0]-RWC[j] drives a predetermined number of bit lines BL and source lines SL allocated thereto. As a result, each of the read/write control circuits RWC[0]-RWC[j] controls the read operation and the write operation with respect to the memory cells MC connected to the predetermined number of bit lines BL and source lines SL.

Each of the read/write control circuits RWC[0]-RWC[j] includes a column selector CSEL, a sense amplifier SA, and a write driver WTD. Here, a read/write control circuit RWC[0] is described as a representative example. The column selector CSEL selects any of the bit lines BL and the source lines SL from a predetermined number of bit lines BL and source lines SL, for example, based on a signal from the address decoder ADEC and the address signal ADR. Then, the column selector CSEL connects the selected bit line BL and source line SL to a global bit line GBL and a global source line GSL, respectively.

In the write operation of the data signal DT[0] (DTi[0]), the write driver WTD applies a predetermined voltage as described with reference to FIG. 3 between the selected bit line BL and source line SL via the global bit line GBL and the global source line GSL. Note that, more specifically, the write driver WTD includes a bit line driver that drives the bit line BL and a source line driver that drives the source line SL.

In the read operation of the data signal DT[0] (DTo[0]), the sense amplifier SA applies a predetermined voltage as described with reference to FIG. 3 between the selected bit line BL and source line SL via the global bit line GBL and the global source line GSL. As a result, a read current according to the binary data flows between the global bit line GBL and the global source line GSL via the memory cell MC to be read. The sense amplifier SA determines binary data in the data signal DT[0] (DTo[0]) by amplifying a difference between the read current and a predetermined reference current.

Note that FIG. 2 illustrates a configuration example in which the bit line BL is shared by the normal memory area ARn and the OTP memory area ARo. However, the nonvolatile memory NVM may have a configuration in which the bit line BL is separated between the normal memory area ARn and the OTP memory area ARo. That is, the nonvolatile memory NVM may include, for example, the plurality of divided memory arrays MARY, and the OTP memory area ARo may be a part of the plurality of memory arrays MARY.

### Method of Manufacturing Semiconductor Device

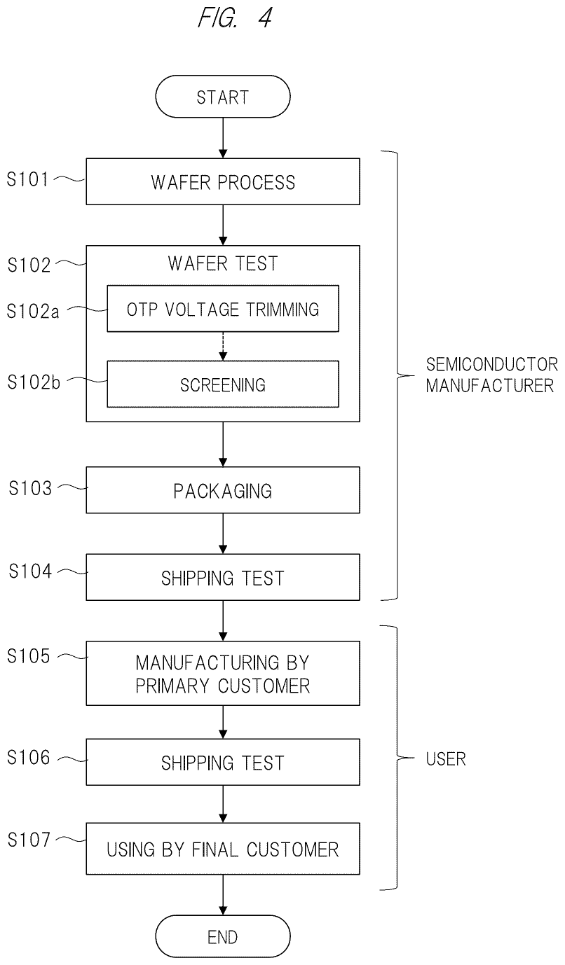

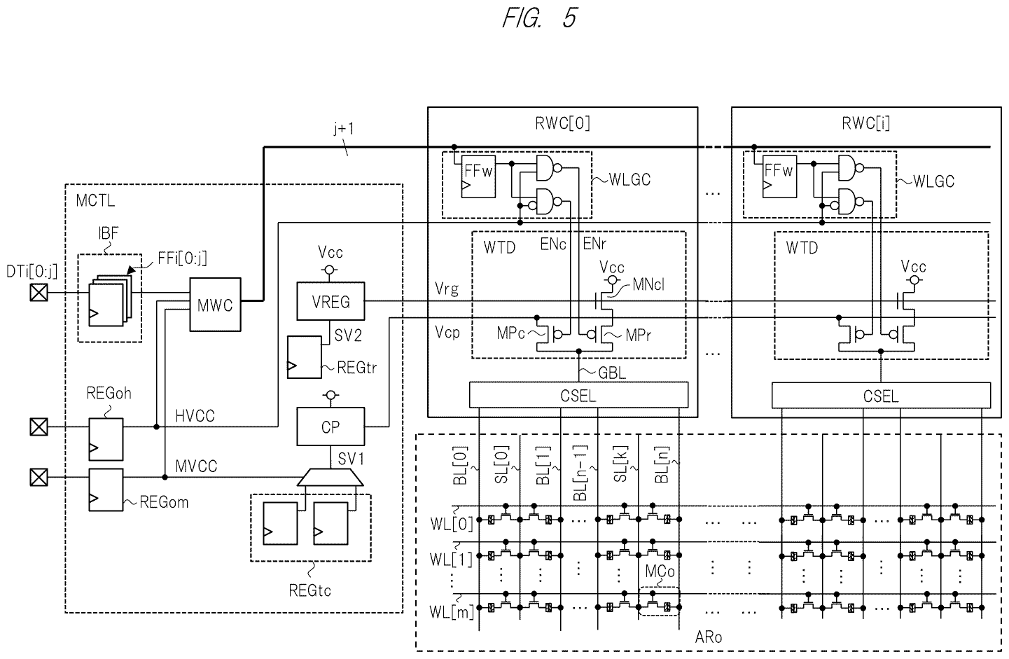

FIG. 4 is a flowchart illustrating an example of a method of manufacturing the semiconductor device according to an embodiment. The flow includes a wafer process step (step S101), a wafer test step (step S102), a packaging step (step S103), a shipping test step (step S104), a manufacturing step by a primary customer (step S105), a shipping test step (step S106), and a using step by a final customer (step S107). The flow from step S101 to step S104 is a flow by a semiconductor manufacturer. Meanwhile, the flow from step S105 to step S107 is a flow by the user.

The wafer process step (step S101) is a step of forming the plurality of semiconductor devices DEV including the nonvolatile memory NVM as illustrated in FIGS. 1 and 2 on a semiconductor wafer using various semiconductor manufacturing devices. The wafer test step (step S102) is a step of testing the semiconductor wafer on which the plurality of semiconductor devices DEV are formed, using a probe inspection device. As described in detail below, the wafer test step (step S102) includes an OTP voltage trimming step (step S102a) and a screening step (step S102b).

The packaging step (step S103) is a step of dividing a semiconductor wafer into the plurality of semiconductor devices DEV using a dicing device and assembling the semiconductor devices DEV determined to be a non-defective product in the wafer test step (step S102) into a package using an assembling device. The shipping test step (step S104) is a step of testing the packaged semiconductor device DEV using a semiconductor tester. Then, the semiconductor device DEV determined as a non-defective product in the test is shipped to the primary customer.

The manufacturing step by the primary customer (step S105) is a step of manufacturing an intermediate product by mounting the shipped semiconductor device DEV on a printed circuit board or the like together with other components. The shipping test step (step S106) is a step of testing the intermediate product. Then, the intermediate product determined to be a non-defective product in the test is shipped to the final customer. The using step by a final customer (step S107) is a step of assembling a final product including the intermediate product and then appropriately using the final product.

Here, the OTP memory area ARo illustrated in FIG. 2 is used for writing trimming data, repair data, and the like. The repair data is, for example, data for replacing the word line WL or the bit line BL determined to be a defect in the wafer test step (step S102) with a redundant word line or bit line provided in the redundant area. Trimming data, repair data, and the like are written in the wafer test step (step S102).

In the wafer test step, any external power supply voltage Vcc can be applied from the probe inspection device to the semiconductor device DEV. Therefore, a high voltage necessary for writing to the OTP memory area ARo can be secured. Meanwhile, due to the writing, that is, the application of a high voltage to the bit line BL, for example, a defect may occur in the normal memory area ARn or the like. However, such a defect can be detected in the wafer test step (step S102) or the shipment test step (step S104). Therefore, the semiconductor device DEV to be a defective product can be prevented from flowing out to the primary customer.

Meanwhile, in recent years, there is a growing demand to write, for example, security information, boot information, and the like in addition to trimming data, repair data, and the like in the OTP memory area ARo. Specifically, examples of the security information include an “anti-rollback counter” for preventing a rolling back attack of rolling back a version of a communication protocol. Examples of the boot information include a first stage boot loader (FSBL) which is a code executed first immediately after the start.

Such security information, boot information, and the like are necessary to be written not only in the wafer test step (step S102) but also in the manufacturing step by a primary customer (step S105) or the using step by a final customer (step S107). Along with this, the following three points may be problematic mainly. As a first problem, (A) a user, that is, a primary customer or a final customer cannot always apply any external power supply voltage Vcc to the semiconductor device DEV unlike the semiconductor manufacturer. Therefore, there is concern that a high voltage necessary for writing to the OTP memory area ARo cannot be secured. For example, in FIG. 3, when the external power supply voltage Vcc is lower than 2.5 V, a necessary high voltage cannot be secured.

As a second problem, (B) on the assumption that a user writes into the OTP memory area ARo, the write voltage used at this time is not necessarily appropriate. Therefore, it is required to predetermine an appropriate write voltage that is neither too small nor too large in consideration of manufacturing variations of the semiconductor wafer. Summarizing (A) and (B), it is necessary to guarantee a reliable write operation to the MTJ-OTP memory cell by the user by a semiconductor manufacturer in advance.

As a third problem, (C) when a user writes into the OTP memory cell MCo, it is likely that a defect occurs in another memory cell MC sharing the bit line BL with the OTP memory cell MCo due to application of a high voltage to the bit line BL. The occurrence of such a defect itself is a problem for a user, unlike a semiconductor manufacturer. Therefore, it is necessary for a semiconductor manufacturer to guarantee in advance that such a defect does not occur.

As a supplement to (A) to (C), first, in the wafer test step (step S102), the write voltage can be arbitrarily determined. Therefore, for example, by using a slightly excessive write voltage or the like, writing can be reliably performed in the OTP memory area ARo. Even when a defect occurs, for example, in the normal memory area ARn or the like due to such a write voltage, it is possible to repair the semiconductor device or exclude the semiconductor device as a defective product. Therefore, unlike the user, no particular problem occurs as long as writing is performed in the OTP memory area ARo by the semiconductor manufacturer.

### Write Operation to OTP Memory Area

FIG. 5 is a circuit block diagram illustrating a configuration example of a main part focusing on a write operation to the OTP memory area ARo in FIG. 2. FIG. 5 illustrates the OTP memory area ARo having the OTP memory cell MCo, J read/write control circuits RWC[0]-RWC[j] that write into the OTP memory cell MCo, and the memory control circuit MCTL that controls a write operation. In the specification, the J read/write control circuits RWC[0]-RWC[j] are collectively referred to as read/write control circuits RWC.

The memory control circuit MCTL includes an input buffer IBF, an OTP voltage select register REGoh, a write number selection register REGom, a write controller MWC, a voltage regulator circuit VREG, a trimming register REGtr, a charge pump circuit CP, and a trimming register REGtc. The input buffer IBF includes, for example, J flip-flops FFi[0]-FFi[j]. As a result, the input buffer IBF latches the J bits of data signals DTi[0:j] input from the outside.

The charge pump circuit CP generates a boost voltage Vcp by boosting the input power supply voltage, here, the external power supply voltage Vcc. The trimming register (first trimming register) REGtc holds a voltage setting value (first voltage setting value) SV1 that defines the magnitude of the boost voltage Vcp. The voltage regulator circuit VREG generates a regulator voltage Vrg by stepping down the external power supply voltage Vcc. The trimming register (second trimming register) REGtr holds a voltage setting value (second voltage setting value) SV2 that defines the magnitude of the regulator voltage Vrg. Note that details of the OTP voltage select register REGoh, the write number selection register REGom, and the write controller MWC are described below.

The memory area ARo includes “m+1” word lines WL [0]-WL [m]. In addition, the memory area ARo includes “n+1” bit lines BL[0]-BL[n] and “k+1” (=(n+1)/2) source lines SL[0]-SL[k] for one read/write control circuit RWC. Accordingly, the memory area ARo includes “(m+1)*(n+1)” OTP memory cells MCo for one read/write control circuit RWC. Examples thereof include n=31 and k=15.

The read/write control circuit RWC includes the column selector CSEL, the write driver WTD, and a write logic circuit WLGC. As described in FIG. 2, the column selector CSEL selects one bit line BL from “n+1” bit lines BL[0]-BL[n]. The write driver WTD, here, the bit line driver, applies the boost voltage Vcp or the regulator voltage Vrg to the selected bit line BL via the global bit line GBL.

That is, the write driver WTD applies the boost voltage Vcp or the regulator voltage Vrg between the selected bit line BL and the source line SL in a state where 0 V is applied to the source line SL by the source line driver (not illustrated). As a result, the write driver WTD writes one of the binary data, for example, the “0” level, to the OTP memory cell MCo connected to the selected word line WL and the selected bit line BL.

The write driver WTD includes, for example, an nMOS transistor MNcl for clamping and two pMOS transistors MPc and MPr for voltage selection. The nMOS transistor MNcl inputs the external power supply voltage Vcc to the drain and inputs the regulator voltage Vrg to the gate. As a result, the nMOS transistor MNcl outputs the regulator voltage Vrg from the source, specifically, the regulator voltage Vrg to which a decrease by a threshold voltage is added.

The pMOS transistor MPc inputs the boost voltage Vcp to The pMOS transistor MPr receives the regulator the source. voltage Vrg from the nMOS transistor MNcl to the source. The on/off states of pMOS transistors MPc and MPr are controlled by enable signals ENc and ENr, respectively. The enable signals ENc and ENr are controlled so that only one of the enable signals ENc and ENr is an “L” pulse signal having a predetermined write pulse width, that is, an on-pulse signal. Alternatively, the enable signals ENc and ENr are both controlled to maintain the “H” level, that is, the off level.

The write logic circuit WLGC includes a flip-flop FFw and various logic gates that control the enable signals ENc and ENr using an output of the flip-flop FFw as an input. When the flip-flop FFw holds the “L” level, the write logic circuit WLGC controls both the enable signals ENc and ENr to the “H” level, that is, the off level. Meanwhile, when the flip-flop FFw holds the “H” level, the write logic circuit WLGC controls one of the enable signals ENc and ENr to the “L” level, that is, to the on level, and controls the other to the “H” level, that is, to the off level.

Therefore, by appropriately controlling the value of the flip-flop FFw, the write logic circuit WLGC can perform control so that only one of the enable signals ENc and ENr becomes the “L” pulse signal. The write controller MWC in the memory control circuit MCTL appropriately controls the value of the flip-flop FFw based on the data signals DTi[0:j] latched in the input buffer IBF.

As a specific example, when the data signal DTi[0] is at the “0” level, the write controller MWC appropriately controls the value of the flip-flop FFw of the read/write control circuit RWC[0]. As a result, one of the enable signals ENc and ENr becomes an “I” pulse signal. Meanwhile, when the data signal DTi[0] is at the “1” level, the write controller MWC writes the “L” level to the flip-flop FFw of the read/write control circuit RWC[0]. As a result, both the enable signals ENc and ENr maintain the “H” level.

Here, the OTP voltage select register REGoh in the memory control circuit MCTL holds a selection value HVCC defining a voltage supply source. Which one of the enable signals ENc and ENr is to be controlled to the “L” pulse signal is defined by the value of the selection value HVCC. That is, the OTP voltage select register REGoh causes the write driver WTD to select either the boost voltage Vcp or the regulator voltage Vrg via the write logic circuit WLGC.

In this example, when the selection value HVCC is at the “H” level, the enable signal ENr becomes an “L” pulse signal via the write logic circuit WLGC. Accordingly, the write driver WTD selects the regulator voltage Vrg. Meanwhile, when the selection value HVCC is at the “L” level, the enable signal ENc becomes an “L” pulse signal via the write logic circuit WLGC. Accordingly, the write driver WTD selects the boost voltage Vcp.

Note that when selecting the regulator voltage Vrg, the write driver WTD can flow a large write current by the external power supply voltage Vcc. In this case, the write drivers WTD in the J read/write control circuits RWC can simultaneously write to the J OTP memory cells MCo. Meanwhile, when selecting the boost voltage Vcp, the write driver WTD can flow only a certain write current due to the current supply capability of the charge pump circuit CP. In this case, the number of simultaneous writes is K smaller than J, for example, K=4 or less.

However, the current supply capability of the charge pump circuit CP may vary depending on the magnitude of the external power supply voltage Vcc input to the charge pump circuit CP. For example, in the case of “Vcc<2.0 V”, K=1. Meanwhile, in the case of “2.0 V<Vcc<2.5 V”, for example, K=2 or K=4. The number of simultaneous writes is desirably as large as possible from the viewpoint of shortening the time required for writing.

Therefore, in FIG. 5, when the boost voltage Vcp is selected, the write number selection register REGom for selecting whether the number of simultaneous writes is one or K, which is two or more, is provided. The write number selection register REGom holds a selection value MVCC that defines the number of simultaneous writes. For example, in the case of “Vcc<2.0 V”, the selection value MVCC is defined to the “L” level. Meanwhile, in the case of “2.0 V<Vcc<2.5 V”, the selection value MVCC is defined to the “H” level. Note that the OTP voltage select register REGoh and the write number selection register REGom can also be configured with another bit in one register.

The selection values HVCC and MVCC are arbitrarily defined by a semiconductor manufacturer or a user. Specifically, in the wafer test step (step S102) illustrated in FIG. 4, for example, the semiconductor manufacturer can determine the selection values HVCC and MVCC via a probe inspection device, a test terminal, and the like. Meanwhile, in the manufacturing step by a primary customer (step S105) or the using step by a final customer (step S107), the user can define the selection values HVCC and MVCC, for example, via the processor PRC and the bus BS.

At this time, the user may define the selection values HVCC and MVCC based on the magnitude of the external power supply voltage Vcc to be used. As an example, when the external power supply voltage Vcc is higher than 2.5 V to some extent, the user may define the selection value HVCC for the voltage supply source to the “H” level. Meanwhile, in the case of “2.0 V<Vcc<2.5 V”, the user may define the selection value HVCC for the voltage supply source to the “L” level and the selection value MVCC for the number of simultaneous writes to the “H” level, respectively. In the case of “Vcc<2.0 V”, the user may define the selection value HVCC to the “L” level and the selection value MVCC to the “L” level.

of The write controller MWC controls the number simultaneous writes to the OTP memory area ARo according to the selection values HVCC and MVCC. Specifically, when the selection value HVCC is at the “H” level, the write controller MWC controls, for example, the flip-flops FFw in the J read/write control circuits RWC[0]-RWC[j] in parallel based on the J bits of the data signals DTi[0:j].

Meanwhile, when the selection value HVCC is at the “L” level, the write controller MWC controls the flip-flops FFw in the K read/write control circuits RWC in parallel based on K bits of the corresponding data signals DTi. At this time, the write controller MWC defines the value of K based on the selection value MVCC.

As described above, in the configuration example of FIG. 5, the write driver WTD that selectively applies the boost voltage Vcp or the regulator voltage Vrg is provided between the bit line BL and the source line SL. As a result, (A) the user can also secure a high voltage necessary for writing into the OTP memory area ARo. That is, even when the external power supply voltage Vcc corresponding to the necessary write voltage cannot be secured, the necessary write voltage can be secured using the charge pump circuit CP.

In addition, by providing the OTP voltage select register REGoh, it is possible to select the boost voltage Vcp or the regulator voltage Vrg by user setting. As a specific example, when the user can secure the desired external power supply voltage Vcc, it is preferable to cause the write driver WTD to select the regulator voltage Vrg. As a result, since the number of simultaneous writes can be increased as compared with the case of using the boost voltage Vcp, it is possible to shorten the time required for writing. In addition, by providing the write number selection register REGom, the time required for writing can be reduced as much as possible even when the boost voltage Vcp is used.

Further, by providing the trimming registers REGtr and REGtc, (B) an appropriate write voltage necessary when the user writes in the OTP memory area ARo can be predetermined. More specifically, in the OTP voltage trimming step (step S102a) illustrated in FIG. 4, as described below, an appropriate write voltage is defined by appropriately operating the trimming registers REGtr and REGtc.

### Details of OTP Voltage Trimming Step

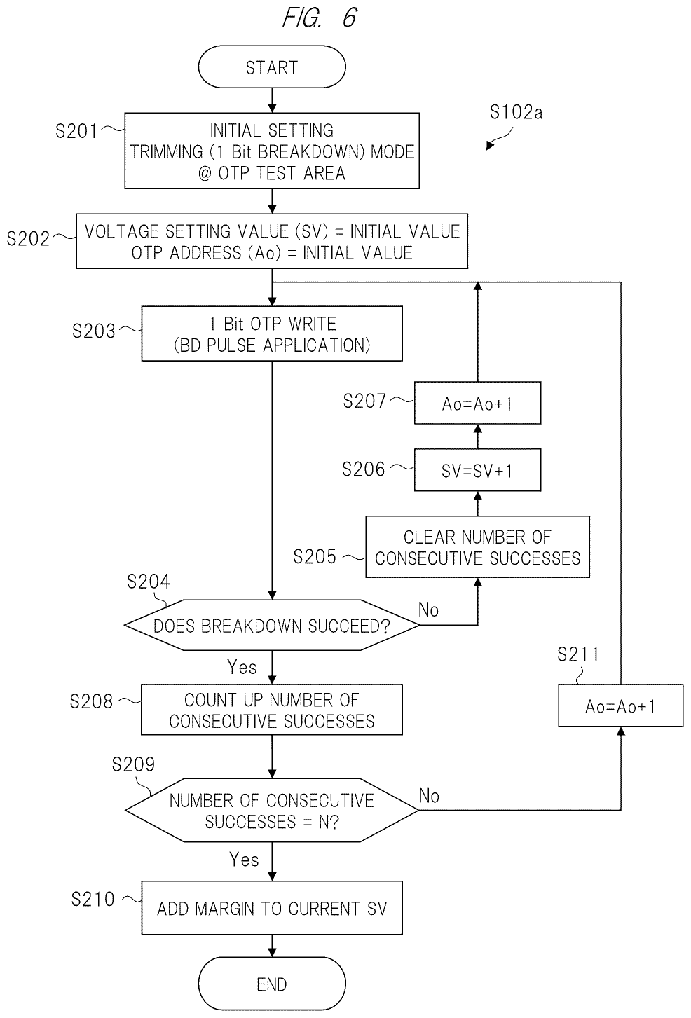

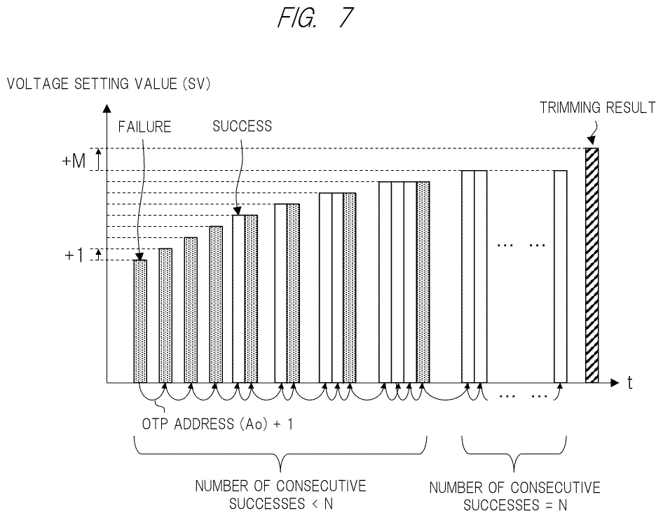

FIG. 6 is a flowchart illustrating an example of detailed processing contents of the OTP voltage trimming step (step S102a) in FIG. 4. FIG. 7 is a schematic diagram illustrating a specific operation example based on the flow illustrated in FIG. 6. In the OTP voltage trimming step (step S102a), at least one of the first voltage setting value SV1 by the trimming register REGtc and the second voltage setting value SV2 by the trimming register REGtr is set as the voltage setting value SV to be trimmed. In the OTP voltage trimming step, writing is performed into the plurality of OTP memory cells MCo one by one.

Then, as illustrated in FIG. 7, in N (N is an integer of 2 or more) OTP memory cells MCo in the plurality of OTP memory cells MCo, the voltage setting value SV is sequentially changed by +1 in the high voltage direction until writing with the same voltage setting value SV succeeds in succession. Specifically, as illustrated in FIG. 7, when the OTP writing fails, the voltage setting value SV is changed. Furthermore, in order to eliminate the influence of accumulation of OTP writing, an OTP address Ao, that is, the OTP memory cell MCo to be written is also changed. Meanwhile, when the OTP writing succeeds, while the voltage setting value SV is maintained, only the OTP address Ao is changed.

Then, such processing is repeatedly executed until the OTP writing succeeds N times in succession. When the OTP writing succeeds N times in succession, a predetermined margin “+M” in the high voltage direction is added to the current voltage setting value SV in order to ensure more reliable success in a range in which the voltage does not become excessive. The value of +M may be, for example, a small value such as +1 or +2. The voltage setting value SV to which this margin is added is a trimming result of the first voltage setting value SV1 or the second voltage setting value SV2.

The flow illustrated in FIG. 6 is performed using, for example, a probe inspection device. In FIG. 6, first, the probe inspection device performs initial setting on the nonvolatile memory NVM (step S201). By the initial setting, the nonvolatile memory NVM is set to, for example, a test mode for trimming in which the voltage setting value SV can be arbitrarily changed. In the test mode for trimming, the OTP writing is performed one bit by one bit using the OTP test area provided in the OTP memory area ARo. In this case, the OTP address Ao represents one of the plurality of OTP memory cells MCo, and the one is defined as the target OTP memory cell MCo.

As a specific example, in FIG. 5, it is assumed that the area of the plurality of OTP memory cells MCo connected to the word line WL[0] is the OTP test area. In this case, for example, the probe inspection device sequentially controls the address signal to the column selector CSEL while setting only one bit of the data signal DTi[0] in the data signals DTi[0:j] to the “0” level. As a result, OTP writing is performed one bit by one bit into “n+1” OTP memory cells MCo allocated to the column selector CSEL in the read/write control circuit RWC[0]. Thereafter, for example, while only the data signal DTi[1] is set to the “0” level, similar processing may be performed.

In FIG. 6, after step S201, the probe inspection device defines the voltage setting value SV to an initial value, for example, a minimum value and defines the OTP address Ao to an initial value (step S202). Subsequently, the probe inspection device causes the nonvolatile memory NVM to perform OTP writing of one bit (step S203). That is, the nonvolatile memory NVM performs writing to the target OTP memory cell MCo designated by the OTP address Ao using the current voltage setting value SV.

Next, the probe inspection device causes the nonvolatile memory NVM to perform a read operation of the target OTP memory cell MCo. Then, the probe inspection device determines whether writing in the target OTP memory cell MCo, that is, dielectric breakdown (BD) succeeds based on the read data signal DT[0:j] (step S204).

Here, when the determination result in step S204 fails (“No”), the probe inspection device clears the held number of consecutive successes (step S205). Then, the probe inspection device changes the voltage setting value SV in the high voltage direction (step S206), changes the OTP address Ao, that is, the target OTP memory cell MCo, and returns to step S203 (step S207).

Meanwhile, when the determination result in step S204 succeeds (“Yes”), the probe inspection device counts up the held number of consecutive successes (step S208). Then, when the number of consecutive successes does not reach the value of N (step S209: No), the probe inspection device changes the OTP address Ao, that is, the target OTP memory cell MCo, and returns to step S203. When the number of consecutive successes reaches the value of N (step S209: Yes), the probe inspection device adds a margin in the high voltage direction to the current voltage setting value SV (step S210).

As a result, the probe inspection device confirms the voltage setting value SV to which the margin is added as the trimming result of one of the first voltage setting value SV1 or the second voltage setting value SV2. The voltage setting value SV confirmed as the trimming result is written in a trimming data storage area provided in the OTP memory area ARo. The semiconductor device DEV loads the voltage setting value SV written in the trimming data storage area, that is, the trimming value to one of the trimming registers REGtc and REGtr at the time of normal activation.

By using the OTP voltage trimming step as described above, it is possible to define an appropriate write voltage necessary at this time on the premise that (B) the user performs writing into the OTP memory area ARo. That is, it is possible to define an appropriate write voltage that is neither too small nor too manufacturing variations of the large in consideration of semiconductor wafer. As a result, it is possible to guarantee a reliable write operation to the MTJ-OTP memory cell by the user by a semiconductor manufacturer in advance. Note that the OTP voltage trimming step may be performed, for example, on all the semiconductor devices DEV or may be performed on a plurality of or one semiconductor device DEV defined for each semiconductor wafer as a representative.

### Details of Voltage Regulator Circuit and Charge Pump Circuit

FIG. 8 is a circuit diagram illustrating a detailed configuration example of the voltage regulator circuit VREG in FIG. 5. The voltage regulator circuit VREG illustrated in FIG. 8 includes a reference voltage generation circuit VREFG, a regulator voltage generation circuit VRGG, and a selection circuit SELv2. The reference voltage generation circuit VREFG includes a pMOS transistor MP1, a resistance voltage divider circuit RDIV, and an amplifier circuit AMP1.

The pMOS transistor MP1 and the resistance voltage divider circuit RDIV are connected in series between the external power supply voltage Vcc and a ground power supply voltage GND. The amplifier circuit AMP1 controls the gate voltage of the pMOS transistor MP1 so that the voltage at a fixed voltage node in the resistance voltage divider circuit RDIV matches a band gap voltage Vbg. As a result, the resistance voltage divider circuit RDIV outputs a plurality of reference voltages Vref<P:0> having different voltage values with a constant step width from a plurality of, here, “P+1” resistance voltage divider nodes. The selection circuit SELv2 outputs any one of the plurality of reference voltages Vref<P:0> as a reference voltage Vref2 based on the voltage setting value SV2 from the trimming register REGtr.

The regulator voltage generation circuit VRGG includes an nMOS transistor MNclR, a pMOS transistor MPrR, a current source CS, and an amplifier circuit AMP2. The nMOS transistor MNclR, the pMOS transistor MPrR, and the current source CS are connected in series between the external power supply voltage Vcc and the ground power supply voltage GND. The amplifier circuit AMP2 controls the gate voltage of the nMOS transistor MNclR so that the voltage of a node Ngbl serving as the drain of the pMOS transistor MPrR matches the reference voltage Vref2 from the selection circuit SELv2. At the same time, the amplifier circuit AMP2 outputs the gate voltage as the regulator voltage Vrg.

The nMOS transistor MNclR and the pMOS transistor MPrR are replica transistors of the nMOS transistor MNcl and the pMOS transistor MPr in the write driver WTD illustrated in FIG. 5, respectively. In addition, the current value of the current source CS is set to, for example, a write current value necessary for OTP writing to one OTP memory cell MCo.

Accordingly, the node Ngbl can be regarded as a replica node of the global bit line GBL. As a result, the amplifier circuit AMP2 outputs the gate voltage of the nMOS transistor MNcl necessary for matching the voltage of the global bit line GBL with the reference voltage Vref2 as the regulator voltage Vrg. Note that the pMOS transistor MPrR may be fixed, for example, to an ON state.

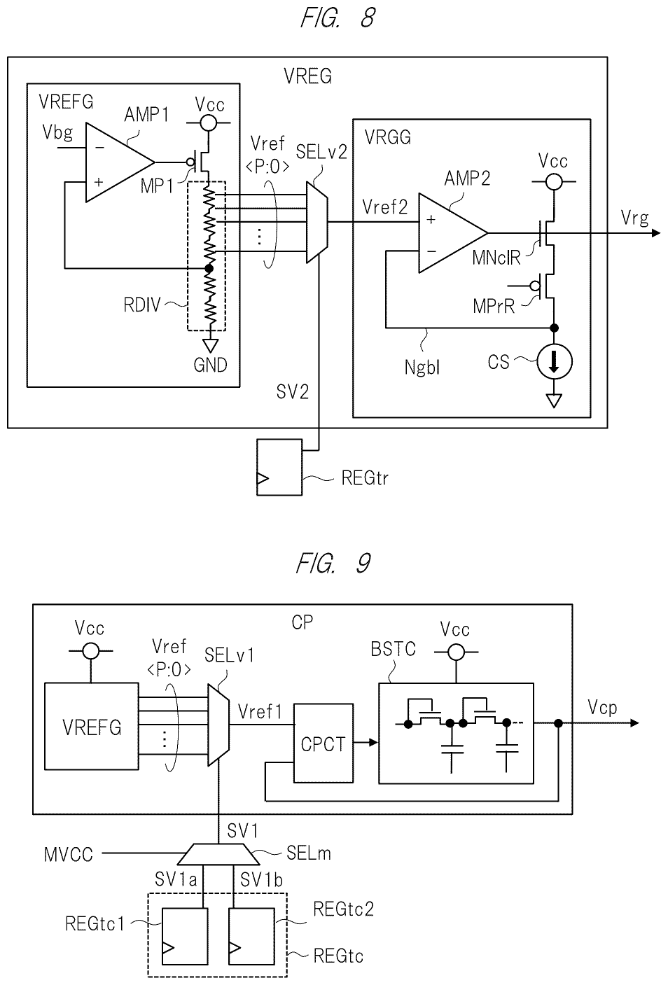

FIG. 9 is a circuit diagram illustrating a schematic configuration example of the charge pump circuit CP in FIG. 5. The charge pump circuit CP illustrated in FIG. 9 includes a selection circuit SELv1, a charge pump control circuit CPCT, and a booster circuit BSTC in addition to the reference voltage generation circuit VREFG similar to that in the case of FIG. 8. The reference voltage generation circuit VREFG outputs the plurality of reference voltages Vref<P:0>. The reference voltage generation circuit VREFG may be shared with the voltage regulator circuit VREG illustrated in FIG. 8.

The selection circuit SELv1 outputs any one of the plurality of reference voltages Vref<P:0> as a reference voltage Vref1 based on the voltage setting value SV1 from the trimming register REGtc. Here, the trimming register REGtc includes two trimming registers REGtc1 and REGtc2. The trimming register (third trimming register) REGtc1 holds a voltage setting value SV1a when the selection value MVCC is at the “L” level, that is, when the number of simultaneous writes is one. The trimming register (fourth trimming register) REGtc2 holds a voltage setting value SV1b when the selection value MVCC is at the “H” level, that is, when the number of simultaneous writes is K, which is two or more.

The two voltage setting values SV1a and SV1b from the two trimming registers REGtc1 and REGtc2 are selected by a selection circuit SELm. That is, the selection circuit SELm selects one of the two voltage setting values SV1a and SV1b based on the selection value MVCC and outputs the selected voltage setting value as the voltage setting value SV1 to the selection circuit SELv1.

The booster circuit BSTC has, for example, a configuration in which a plurality of booster stages including a diode and a capacitor are connected in cascade. The booster circuit BSTC generates the boost voltage Vcp by alternately repeating charging of the capacitor and boosting operation of the capacitor. The charge pump control circuit CPCT controls, for example, activation/deactivation of the booster circuit BSTC so that the boost voltage Vcp, specifically, a voltage obtained by resistance-dividing the boost voltage Vcp matches the reference voltage Vref1 from the selection circuit SELv1.

Here, in order to obtain the trimming value of the voltage setting value SV2 illustrated in FIG. 8, for example, the flow illustrated in FIG. 6 may be executed in a state where the external power supply voltage Vcc higher than 2.5 V is applied and the selection value HVCC is set to the “H” level. Also, in order to obtain the trimming value of the voltage setting value SV1a illustrated in FIG. 9, for example, the flow illustrated in FIG. 6 may be executed in a state where the external power supply voltage Vcc lower than 2.0 V is applied and the selection value HVCC is set to the “L” level.

Meanwhile, in order to obtain the trimming value of the voltage setting value SV1b illustrated in FIG. 9, for example, the flow illustrated in FIG. 6 may be executed in a state where the external power supply voltage Vcc of “2.0 V<Vcc<2.5 V” is applied and the selection value HVCC is set to the “L” level. In this case, the flow illustrated in FIG. 6 is performed using not writing in units of one bit but writing in units of K bits of two or more.

However, in some cases, any of the three trimming values in the voltage setting values SV2, SV1a, and SV1b also can be obtained by conversion without performing the flow illustrated in FIG. 6 or the similar flow three times. That is, when the correlation between the three trimming values is known in advance, for example, the remaining two trimming values can be calculated from one trimming value. The correlation is obtained, for example, by using statistical data evaluated in advance.

### OTP Memory Area

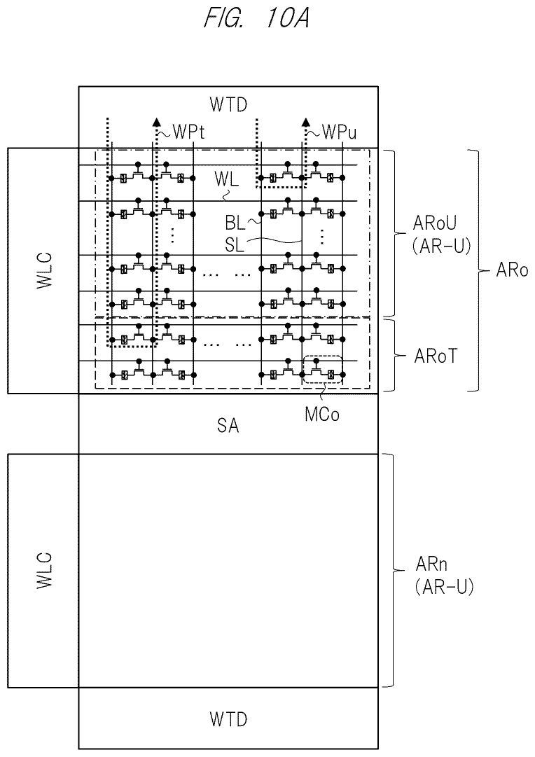

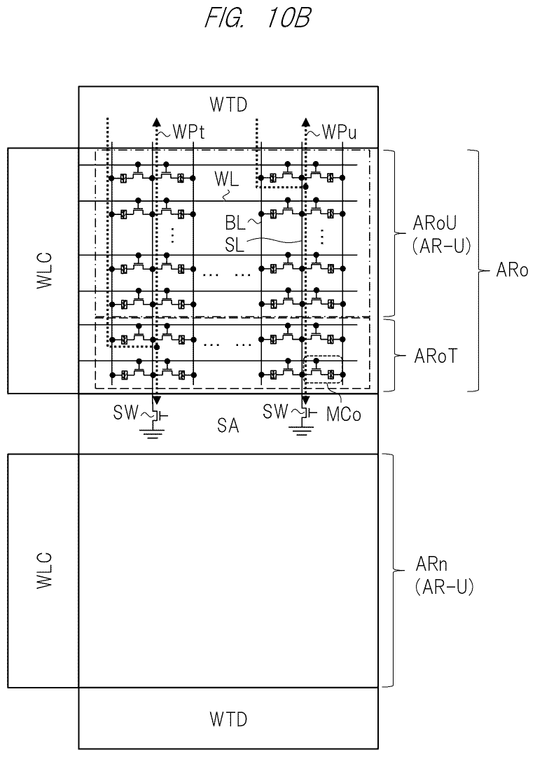

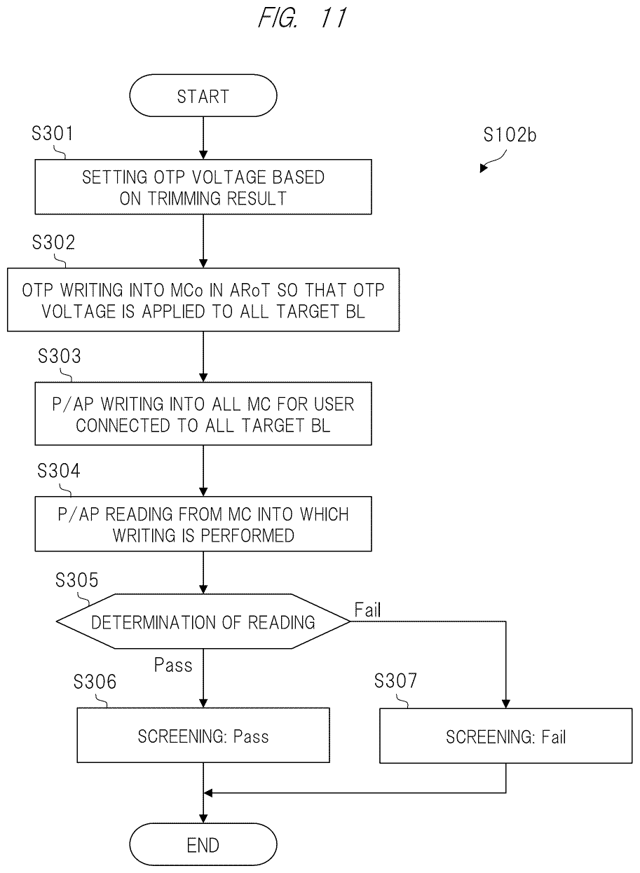

FIGS. 10A and 10B are schematic diagrams illustrating a layout configuration example of the OTP memory area ARo in FIG. 5. In the example illustrated in FIG. 10A, as illustrated in FIG. 2, a plurality of divided memory arrays is provided, and one of the plurality of memory arrays is the OTP memory area ARo. The plurality of memory arrays are divided by a formation area of the sense amplifier SA or a formation area of the write driver WTD.

The OTP memory area ARo includes an OTP user area ARoU and an OTP test area ARoT. The OTP user area ARoU is configured with a part of the plurality of OTP memory cells MCo and is an area that can be freely used by the user. Meanwhile, the OTP test area ARoT is an area that is configured with other parts of the plurality of OTP memory cells MCo and is used in the OTP voltage trimming step (step S102a) illustrated in FIG. 6.

Here, the OTP test area ARoT is disposed at a position separated from the write driver WTD as compared with the OTP user area ARoU. That is, the OTP user area ARoU is allocated to the word line WL on the side close to the write driver WTD. That is, the OTP test area ARoT is allocated to the word line WL on the side far from the write driver WTD.

By using such disposition, a write path WPt from the write driver WTD to the OTP test area ARoT becomes longer than a write path WPu to the OTP user area ARoU. Accordingly, the write voltage necessary for the OTP writing into the OTP test area ARoT becomes higher than the write voltage necessary for the OTP writing into the OTP user area ARoU. As a result, the write operation for the OTP user area ARoU can be more reliably guaranteed by using the write voltage defined in the OTP voltage trimming step (step S102a).

In the layout configuration example illustrated in FIG. 10B, unlike the case of FIG. 10A, the switch SW for connecting the source line SL to the ground power supply voltage GND is provided in the formation area of the sense amplifier SA. In this case, as the write paths WPt and WPu, a path from the OTP memory cell MCo toward the sense amplifier SA side is added to a path returning from the OTP memory cell MCo to the write driver WTD similar to the case of FIG. 10A. Even in this case, generally, since a necessary write voltage is defined mainly on a path from the write driver WTD to the OTP memory cell MCo, it is advantageous to use the same arrangement.

Note that, in the memory array, the dummy word line WL that is not originally used may be provided at a boundary portion with the write driver WTD and a boundary portion with the sense amplifier SA. The dummy word line WL can be allocated to the OTP test area ARoT. This can reduce area overheads. In the example illustrated in FIGS. 10A and 10B, the other one of the plurality of memory arrays is the normal memory area ARn described with reference to FIG. 2. The normal memory area ARn is configured with a user area AR-U that can be freely used by the user together with the OTP user area ARoU.

### Details of Screening Step

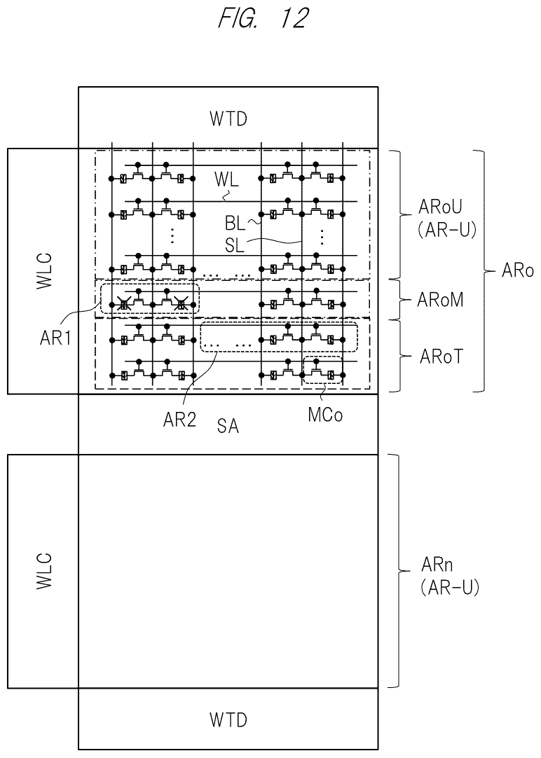

FIG. 11 is a flowchart illustrating an example of detailed processing contents of the screening step (step S102b) in FIG. 4. FIG. 12 is a supplementary view illustrating a part of processing contents in FIG. 11. The flow illustrated in FIG. 11 is performed using, for example, a probe inspection device.

First, the probe inspection device causes, for example, the trimming register REGtr of the nonvolatile memory NVM to hold the voltage setting value SV2 to be the trimming result in the OTP voltage trimming step (step S102a) (step S301). Next, the nonvolatile memory NVM writes into the OTP memory cell MCo in the OTP test area ARoT so that the OTP voltage based on the voltage setting value SV2, that is the write voltage is applied to all the bit line BL to which the plurality of OTP memory cells MCo are connected based on the instruction from the probe inspection device (step S302).

Here, FIG. 12 illustrates a layout configuration example similar to the case of FIG. 10A. However, here, unlike the case of FIG. 10A, a manufacturer area ARoM is further added into the OTP memory area ARo. For example, trimming data and the like are written into the manufacturer area ARoM. The voltage setting value SV2 that is a trimming result in the OTP voltage trimming step (step S102a) may be written into the manufacturer area ARoM, for example, before the screening step (step S102b).

In the example illustrated in FIG. 12, the voltage setting value SV2 that is a trimming result is written into an area AR1. In this case, the boost voltage Vcp or the regulator voltage Vrg defined in the OTP voltage trimming step (step S102a) is already applied to the bit line BL included in the area AR1, specifically, the bit line BL into which the writing at the “0” level is performed. Therefore, the OTP memory cell MCo in the OTP test area ARoT to be written in step S302 and the bit line BL may be the OTP memory cell MCo in an area AR2 excluding the bit line BL included in the area AR1. Thus, the test time can be shortened.

Subsequently, the nonvolatile memory NVM performs P writing or AP writing into the memory cell MC for the user connected to all the bit lines BL to which the OTP memory cell MCo is connected based on an instruction from the probe inspection device (step S303). The memory cell MC for the user is the OTP memory cell MCo included in the OTP user area ARoU in FIG. 10A. In addition, for example, as illustrated in FIG. 2, when the bit line BL is shared by the OTP user area ARoU and the normal memory area ARn, the memory cell MC for the user also includes the normal memory cell MCn in the normal memory area ARn.

Thereafter, the probe inspection device verifies that P reading or AP reading can be performed by causing the nonvolatile memory NVM to perform a read operation (steps S304 and 305). In the example illustrated in FIG. 10A, the probe inspection device determines a pass/fail relating to reading of the “0” level or the “1” level from the OTP memory cell MCo in the OTP user area ARoU (step S305). When the determination result is a failure, the probe inspection device determines that the screening result fails (step S307).

Meanwhile, when the determination result in step S305 is a pass, the probe inspection device determines that the screening result is a pass (step S306). By the processing of steps S302 to S305, (C) when the user performs writing into the OTP memory cell MCo, it is possible to guarantee the user that no defect occurs in another memory cell MC sharing the bit line BL with the OTP memory cell MCo due to the application of the high voltage to the bit line BL.

### Modification

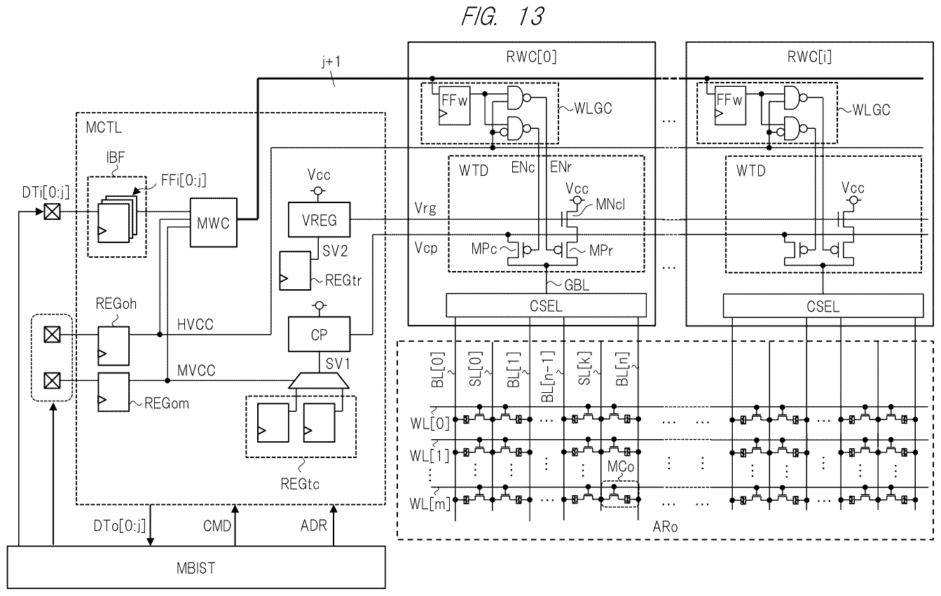

FIG. 13 is a circuit block diagram illustrating configuration example obtained by modifying FIG. 5. In FIG. 13, a memory built in self test (BIST) circuit MBIST is added to the configuration example illustrated in FIG. 5. For example, the memory BIST circuit MBIST outputs the command signal CMD, the address signal ADR, and the data signals DTi[0:j] to the memory control circuit MCTL according to a start signal or the like from the probe inspection device or inputs data signals DTo[0:j] from the memory control circuit MCTL to determine a pass/failure. Further, the memory BIST circuit MBIST can operate the OTP voltage select register REGoh, the write number selection register REGom, and the trimming registers REGtr and REGtc.

As a result, the memory BIST circuit MBIST performs a self-test of the nonvolatile memory NVM instead of the probe inspection device. As one of the self-test, the memory BIST circuit MBIST controls the sequence of the OTP voltage trimming step (step S102a) illustrated in FIG. 6. As a result, each of the plurality of semiconductor devices DEV formed on the semiconductor wafer can autonomously obtain a trimming value optimum for the own device. In addition, the memory BIST circuit MBIST may control the sequence of the screening step (step S102b) illustrated in FIG. 11.

By providing the memory BIST circuit MBIST, the number of semiconductor devices DEV that can be tested at the same time can be increased within a limited resource range of the probe inspection device. As a result, the test cost can be reduced. Note that the memory BIST circuit MBIST can be configured with, for example, a command generation circuit, an address generation circuit, a data generation circuit, a data determination circuit, and a sequencer circuit that controls these circuits.

### Main Effects of Embodiments

As described above, in the method according to the embodiment, either the regulator voltage obtained by stepping down the power supply voltage or the boost voltage obtained by boosting the power supply voltage can be selectively used as the write voltage to the MTJ-OTP memory cell. Further, optimum values of these voltages can be defined by the OTP voltage trimming step by a semiconductor manufacturer. As a result, it is possible to guarantee a reliable write operation into the OTP memory cell by the user. Furthermore, in the method according to the embodiment, a screening step is provided after the OTP voltage trimming step. As a result, it is possible to guarantee that no defect occurs due to the write operation into the OTP memory cell by the user.

Although the invention conceived by the present inventors is specifically described based on the embodiments, the present invention is not limited to the above embodiments, and various modifications can be made without departing from the gist of the present invention. For example, the above-described embodiments are described in detail in order to describe the present invention in an easy-to-understand manner, and are not necessarily limited to those having all the described configurations. In addition, a part of the configuration of one embodiment can be replaced with the configuration of another embodiment, and the configuration of another embodiment can be added to the configuration of one embodiment. In addition, it is possible to add, delete, and replace other configurations for a part of the configuration of each embodiment.

What is claimed is:

1. A method of manufacturing a semiconductor device, the method comprising:
a wafer process step of forming a nonvolatile memory on a semiconductor wafer; and
a wafer test step of testing the semiconductor wafer,
wherein, in the nonvolatile memory,
a plurality of word lines,
a plurality of bit lines arranged to cross the plurality of word lines,
a plurality of source lines arranged side by side in the plurality of bit lines,
a plurality of one time programmable (OTP) memory cells that are arranged in intersection between the plurality of word lines and the plurality of bit lines and include a transistor switch of which an on/off state is controlled by any of the plurality of word lines and a magnetoresistive tunnel junction (MTJ) element storing binary data depending on presence or absence of dielectric breakdown,
a charge pump circuit that generates a boost voltage obtained by boosting a power supply voltage,
a voltage regulator circuit that generates a regulator voltage obtained by stepping down the power supply voltage,
a write driver that writes one of the binary data into any of the plurality of OTP memory cells by applying the boost voltage or the regulator voltage between any of the plurality of bit lines and any of the plurality of source lines,
an OTP voltage select register that causes the write driver to select any one of the boost voltage or the regulator voltage,
a first trimming register that holds a first voltage setting value for defining a magnitude of the boost voltage, and
a second trimming register that holds a second voltage setting value for defining a magnitude of the regulator voltage
are formed,
wherein the wafer test step is an OTP voltage trimming step, and
wherein the OTP voltage trimming step is a step of sequentially changing the voltage setting value in a high voltage direction, while one of the first voltage setting value or the second voltage setting value is used as a voltage setting value to be trimmed, and writing is performed into the plurality of OTP memory cells one by one, until writing with the same voltage setting value into N OTP memory cells that are two or more in the plurality of OTP memory cells succeeds in succession.

2. The method of manufacturing the semiconductor device according to claim 1,
wherein the OTP voltage trimming step includes:
(A) a step of defining the voltage setting value to an initial value and defining one of the plurality of OTP memory cells to a target OTP memory cell;
(B) a step of writing the target OTP memory cell using the voltage setting value;
(C) a step of determining whether writing into the target OTP memory cell succeeds;
(D1) a step of clearing a number of consecutive successes when a determination result in the step of (C) is a failure, changing the voltage setting value in a high voltage direction, changing the target OTP memory cell, and returning to the step of (B); and
(D2) a step of counting up the number of consecutive successes when the determination result in the step of (C) is a success, changing the target OTP memory cell when the number of consecutive successes does not reach N, and returning to the step of (B).

3. The method of manufacturing the semiconductor device according to claim 2, the method further comprising:
(E) a step of adding a margin in the high voltage direction to the current voltage setting value when the number of consecutive successes in the step of (D2) reaches N, and confirming the voltage setting value to which the margin is added as a trimming result of one of the first voltage setting value or the second voltage setting value.

4. The method of manufacturing the semiconductor device according to claim 2,
wherein a memory built in self test (BIST) circuit that controls a sequence of the OTP voltage trimming step is formed in the nonvolatile memory.

5. The method of manufacturing the semiconductor device according to claim 1,
wherein, in the nonvolatile memory,
an OTP user area that is an area configured with a part of the plurality of OTP memory cells and being freely usable by a user,
an OTP test area that is an area configured with the another part of the plurality of OTP memory cells and used in the OTP voltage trimming step, and
a normal memory area that is an area configured with a normal memory cell for holding binary data in a parallel (P) state or an anti parallel (AP) state and being freely usable by a user
are formed.

6. The method of manufacturing the semiconductor device according to claim 5,
wherein the OTP test area is formed at a position separated from the write driver, compared with the OTP user area.

7. The method of manufacturing the semiconductor device according to claim 5,
wherein the wafer test step further includes a screening step performed after the OTP voltage trimming step, and
wherein the screening step includes:
(F) a step of writing into an OTP memory cell in the OTP test area so that the boost voltage or the regulator voltage defined in the OTP voltage trimming step is applied to all bit lines to which the plurality of OTP memory cells are connected; and
(G) a step of verifying that P reading or AP reading is performed by performing P writing or AP writing on the plurality of memory cells in the OTP user area or the normal memory area, which are the plurality of memory cells connected to all the bit lines after the step of (F).

8. The method of manufacturing the semiconductor device according to claim 7,
wherein, in the step of (F), a bit line, to which the boost voltage or the regulator voltage defined in the OTP voltage trimming step is applied before the step of (F), is excluded from the write target.

9. The method of manufacturing the semiconductor device according to claim 1,
wherein the OTP voltage trimming step includes:
a step of causing the first voltage setting value as the trimming target; and
a step of causing the second voltage setting value as the trimming target.

10. A semiconductor device comprising:
a word line;
a plurality of bit lines arranged to cross the word line;
a plurality of source lines arranged side by side in the bit line;
a plurality of one time programmable (OTP) memory cells that are arranged at intersection between the word line and the plurality of bit lines and include a transistor switch of which an on/off state is controlled by the word line and a magnetoresistive tunnel junction (MTJ) element for storing binary data depending on presence or absence of dielectric breakdown;
a charge pump circuit that generates a boost voltage obtained by boosting a power supply voltage;
a voltage regulator circuit that generates a regulator voltage obtained by stepping down the power supply voltage;
a write driver that writes one of the binary data to any of the plurality of OTP memory cells by applying the boost voltage or the regulator voltage between any of the plurality of bit lines and any of the plurality of source lines; and
an OTP voltage select register that causes the write driver to select any one of the boost voltage or the regulator voltage.

11. The semiconductor device according to claim 10, further comprising:
a first trimming register that holds a first voltage setting value defining a magnitude of the boost voltage; and
a second trimming register that holds a second voltage setting value defining a magnitude of the regulator voltage.

12. The semiconductor device according to claim 11, further comprising:
a write number selection register that selects whether the number of simultaneous writes to the plurality of OTP memory cells is K, which is one or two or more, when the boost voltage is selected,
wherein the first trimming register includes:
a third trimming register that holds the first voltage setting value when the number of simultaneous writes is one, and
a fourth trimming register that holds the first voltage setting value when the number of simultaneous writes is K.

13. The semiconductor device according to claim 12,
wherein the write driver performs simultaneous writing into J OTP memory cells in which J is more than K, when the regulator voltage is selected by the OTP voltage select register.
